(19) United States
(12) Patent Application Publication
(10) Pub. No.: US 2024/0431123 A1
(43) Pub. Date: Dec. 26, 2024

(54) Thread-Based Transistors

(71) Applicant: Trustees of Tufts College, Medford, MA (US)

(72) Inventors: Sameer Sonkusale, Lincoln, MA (US); Rachel Owyeung, Medford, MA (US); Tanuj Kumar, New Delhi (IN)

(21) Appl. No.: 18/274,010

(22) PCT Filed: Jan. 25, 2022
(86) PCT No.: PCT/US2022/013610

§ 371 Date: Jul. 25, 2023

Related U.S. Application Data
(60) Provisional application No. 63/141,145, filed on Jan. 25, 2021.

(51) Int. Cl. H10K 10/46

(52) U.S. Cl. CPC H10K 10/484; H10K 10/464; H10K 10/468; H10K 10/481

(57) ABSTRACT

A thread-based transistor includes a channel thread, a gate wire, and an ion gel. The channel thread includes a textile core that includes a source segment, a drain segment, and a gap segment that is between the source segment and the drain segment. Both the source segment and the drain segment are coated by a conductive coating. The gap segment, however, is coated by a semiconducting material. The ion gel provides electrical coupling between the gap segment and the gate wire.

### RELATED APPLICATIONS

This application claims the benefit of the Jan. 25, 2021 priority date of U.S. Provisional Application 63/141,145, the contents of which are incorporated herein by reference.

### STATEMENT OF GOVERNMENT RIGHTS

This invention was made with government support under grant 1935555 awarded by the National Science Foundation. The government has certain rights in the invention.

### FIELD OF INVENTION

This application pertains to wearable electronics and, in particular, to the manufacture of thread-based transistors and the transistors that result from such manufacture.

### BACKGROUND

Wearable devices have led to major advances in flexible electronics with improved substrates, semiconductors, gate materials, and electrodes. These advances are the result of adapting two-dimensional electronics to non-planar surfaces, such as the surface of the human body and the arrival of flexible displays.

A difficulty that arises in such devices is that some components are difficult to make flexible. Among these are transistors. Although each individual transistor is small, their ubiquity in electronic circuitry means that rigid transistors undermine flexibility of circuits to some extent.

### SUMMARY

In one aspect, the invention includes an article of manufacture that comprises a thread-based transistor having a channel thread, a gate wire, and an ion gel. The channel thread includes a textile core that includes a source segment, a drain segment, and a gap segment that is between the source segment and the drain segment. Both the source segment and the drain segment are coated by a conductive coating. The gap segment, however, is coated by a semiconducting material. The ion gel provides electrical coupling between the gap segment and the gate wire.

Embodiments include those in which the textile core includes linen, those in which the conductive coating includes graphite, and those in which the gate wire includes a gold wire.

In some embodiments, the thread-based transistor is an elastic transistor. Such embodiments include those in which the textile core is elastic.

Embodiments also include those in which the semiconducting coating on the gap segment includes a semiconducting polymer. Examples of suitable semiconducting polymers include poly(3-hexylthiophene) and poly(3,4-ethylenedioxythiophene) polystyrene.

Embodiments further include those in which semiconducting material comprises molybdenum disulfide, those in which it comprises tungsten selenide, those in which it comprises graphene, those in which it comprise carbon nanotubes, and those in which it comprises reduced graphene-oxide.

In some embodiments, the gap segment has an average length of under one millimeter.

Other aspects include those in which the article of manufacture includes clothing that includes wearable electronic circuitry incorporated therein, wherein the transistor is a constituent of the wearable electronic circuitry.

In another aspect, the invention features a process for manufacturing a thread-based transistor that includes a channel thread having a source segment, a drain segment, and a gap segment between the source and drain segments. The process of manufacturing the thread-based transistor includes forming the channel thread by passing a textile core through a stencil set that includes a stencil such that a portion of the textile core that is to become the gap segment is inside the stencil and portions of the textile core that are to become the source and drain segments are outside any stencil, applying a conductive coating onto the portions of the textile core that are outside any stencil, thereby forming the source and drain segments, and removing the stencil set, thereby exposing the gap segment.

Practices include those that include passing the textile core through a hole that extends between opposed first and second surfaces of the stencil. Among these are practices in which the hole transitions between two diameters, the smaller of which is smaller than that of the textile core and passing the textile core through the hole includes passing it through the hole when the hole has its larger diameter and then, with the textile core having safely passed through, causing the hole to transition into its smaller diameter. This results in a tight seal that suppresses seepage of ink beyond the stencil's surface.

Also among the practices are those in which the stencil comprises an elastic material having a hole extending therethrough and passing the textile core though the hole includes stretching the stencil to enlarge the hole and, after the textile core has passed through the hole, releasing the stencil so that the hole now securely grips the textile core, thereby entrapping it in the hole.

In some practices, forming the channel thread includes passing the textile core through the stencil thread one or more additional times, thereby forming additional gap segments on the channel thread. Among these are embodiments in which the additional gap segments are parallel to each other while in the stencil and those in which they are colinear while in the stencil.

Other practices include those in which forming the channel thread includes causing the textile core to pass through projections in the stencil and through recesses that separate the projections from each other. In such practices, each portion of the channel thread that is inside a projection defines one of the gap segments.

Other practices include placement of multiple stencils on the same thread in a manner analogous to beads on a string. Such practices include passing the textile core through a stencil set that includes multiple stencils so as to form additional gap segments.

Practices further include those that include forming multiple gap segments of the same length on a channel thread and forming multiple gap segments of different lengths on a channel thread.

Still other practices include providing a gate wire, coating the gap segment with a semiconducting material, and providing an ion gel between the gate wire and the coated gap segment.

Still other practices include applying the conductive coating by applying liquid carbon ink onto the textile core and onto the stencil.

Also among the practices are those that include incorporating the transistor into flexible circuitry that is on a flexible substrate.

In another aspect, the invention features a method for manufacturing transistors. The method includes sewing a thread through a stencil that has a thickness, thereby defining first portions of the thread and second portions of the thread, each of the second portions being between a pair of first portions. The second portions are masked as a result of the thickness of the stencil. The first portions remain unmasked. The method continues with coating the first portions with a conductive material. Once this is done, the thread is removed from the stencil. The coated first portions of the thread form source and drain terminals of the transistors thus manufactured.

Practices of the method include those in which the conductive material is selected to be carbon ink and those in which the thread is selected to be a linen thread.

The invention provides a way to make flexible thread-based transistors using threads made of textiles. Such threads, when made from biocompatible fibers, interface well with three-dimensional tissues and organs. Such threads are also simple to process. They can be dip coated or fabricated in a reel-to-reel process to achieve high throughputs.

The invention also provides a way to make thread-based transistors in a way that achieves high throughput and without the need for a cleanroom. This permits the manufacture of multiple thread-based transistors that are needed for more complex circuitry, such as amplifiers, transmitters, or microcontrollers. Such circuitry requires many transistors that have consistent electrical properties. Transistors manufactured along the lines disclosed herein are usable in wearable electronics and flexible displays.

The method described herein provides a low-cost, high-throughput and cleanroom-free fabrication method for ion-gel-gated organic thread-based transistors. The manufacturing method relies in part on a three-dimensional flexible “stencil” to fabricate the active channel area gap. The stencil results in a three-dimensional mask for spatially targeted printing on thread-based substrates. The thread is then coated with a conductive ink such as carbon ink.

The resulting channel thread thus includes the drain, source, the semiconductor gap between them, all of which are disposed on a single thread that is in contact with an ion gel. The resulting thread-based transistor is a three-dimensional structure in which the entire circumference of the thread is available for actuation by the gate wire. Since the thread-based transistor is on a thread, its orientation is unrestricted. It can be made vertical or horizontal. It is not confined to a single plane as is the case for conventional transistors in an integrated circuit. In addition, since the transistors are non-planar, it is possible to have two transistors share the same footprint by stacking one on top of the other.

These and other features of the invention will be apparent from the following detailed description and the accompanying figures, in which:

### BRIEF DESCRIPTION OF THE FIGURES

FIG. 1 shows a transistor comprising two threads coupled by a conducting gel;

FIG. 2 shows a channel thread of the type shown in FIG. 1 prior to selective application of conductive coating;

FIG. 3 shows the channel thread of FIG. 2 after selective application of conductive coating;

FIG. 4 shows the channel thread of FIG. 3 following removal of the rectangular prism that functions as a three-dimensional stencil;

FIG. 5 shows multiple textile cores passing through a single stencil;

FIG. 6 shows multiple stencils on the same textile core;

FIG. 7 shows the textile core of FIG. 6 after having been coated with an ink in selected segments thereof and thus transformed into a channel thread;

FIG. 8 shows the channel thread of FIG. 7 with the stencils having been removed;

FIG. 9 shows a textile core passing through a corrugated stencil;

FIG. 10 shows the textile core of FIG. 9 after having been coated with a first ink;

FIG. 11 shows the textile core of FIG. 10 after having been advanced to expose different segments thereof in the recesses of the corrugated stencil;

FIG. 12 shows the newly-exposed segments after having been coated with a second ink;

FIG. 13 shows the textile core of FIG. 9 now coated with different inks in different segments thereof.

FIG. 14 shows a stencil that accommodates two textile cores;

FIG. 15 shows a pressure sensor that uses the stencil and two textile cores shown in FIG. 14;

FIG. 16 shows a pair of stencils that are stacked to avoid a short between two textile cores; and

FIG. 17 shows a flexible substrate that includes the transistor of FIG. 1 incorporated therein.

### DETAILED DESCRIPTION

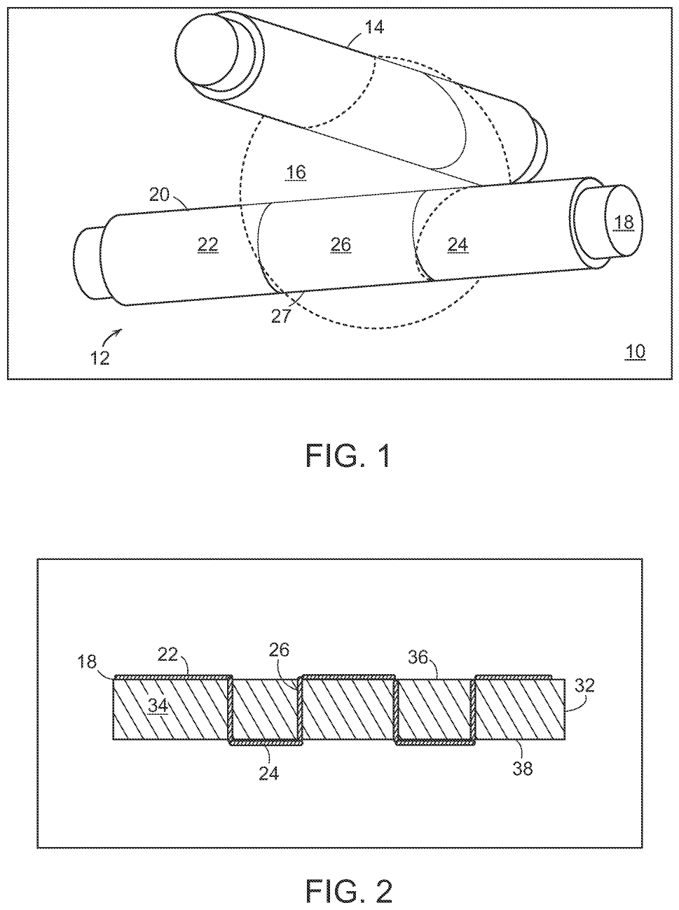

FIG. 1 shows a thread-based transistor 10 comprising a channel thread 12 and a gate wire 14. An ion gel 16 provides electrical coupling between the channel thread 12 and the gate wire 14. Because it is not liquid, the ion gel 16 stays in place. Both the channel thread 12 and the gate wire 14 are flexible. As a result, the thread-based transistor 10 is suitable for use in a wearable article or in an article that conforms to a surface of time-varying shape.

The channel thread 12 comprises a textile core 18 that has been selectively coated by a conductive coating 20 to form a source segment 22, a drain segment 24, and a gap segment 26. The gap segment 26 lies between the source and drain segments 22, 24 and remains uncoated by the conductive coating 20.

The gap segment 26 is coated by a semiconductor coating 27. A suitable semiconductor coating 27 comprises a polymer, which can be applied by dropcasting on the gap segment 26. A suitable polymer is poly(3-hexylthiophene). Another suitable polymer is poly(3,4-ethylenedioxythiophene) polystyrene sulfonate. Other examples of suitable materials for use in the semiconductor coating 27 comprise carbon nanotubes, molybdenum disulfide, and graphene.

Upon application of a voltage at the gate wire 14, ions from the ion gel 16 migrate towards the boundary between the ion gel 16 and the semiconductor coating 27, thus surrounding the boundary and creating a strong electric field within the semiconductor coating 27. The resulting electric field electrostatically dopes the semiconductor coating 27, thus increasing its conductivity, thereby permitting electric current to flow across the gap segment 26 between the source and drain segments 22, 24. Eliminating the applied voltage reverses the process and causes current to stop flowing.

In the illustrated embodiment, the textile core 18 comprises linen thread and the conductive coating 20 comprises graphite that has been applied by brushing liquid carbon ink with a fine brush or spraying it with an aerosol jet. In alternative embodiments, the conductive coating 20 is applied by chemical vapor deposition. In a typical embodiment, the resulting graphite coating has a resistivity of approximately 719±66 ohms per centimeter.

Materials other than linen can be used to form the textile core 18. The material used is preferably one that is resistant to degradation by the various materials to which it is exposed during processing and one that adheres to the conductive coating 20. In some embodiments, the textile core 18 is elastic, as a result of which the transistor is an elastic transistor.

The gate wire 14 has a structure similar to that of the channel thread 12 but without the need for a gap segment 26. As shown in FIG. 1, the gate thread 14 comprises a conducting core 28 and a semiconducting coating 30. In a preferred embodiment, the conducting core 28 comprises a chemically inert metal, such as gold.

The ion gel 16 encompasses the gap segment 26 and the gate thread 14. This permits a voltage applied to the gate thread 14 to control conductivity of the gap segment 26, thus controlling current between the drain segment 24 and the source segment 22. In a preferred embodiment, the ion gel 16 is a colloidal ion gel such as one that comprises silica-based nanoparticles. Other examples of an ion gel 16 are those made from salts, ionic liquids, and deep eutectic solvents

As a result of these exposed segments 26, the coating 20 is discontinuous. In practice, the gap segment 26 is less than a millimeter, and typically on the order of half a millimeter. However, their presence and the need to ensure their uniformity causes some difficulty in efficiently manufacturing the channel thread 12. With such small gap segments 26, even small manufacturing errors will significantly alter electrical properties.

A suitable method for mass production of thread-based transistors 10 features passing the textile core 18 through a stencil 32 as shown in FIG. 2. Those segments of textile core 18 that are destined to become exposed segments 26 are encased within the stencil's interior 34; those that are destined to be source segments 22 lie on the stencil's top surface 36; and those destined to become drain segments 24 lie on the stencil's bottom surface 38. In the latter two cases, a small gap remains between the source and drain segments 22, 24 and the corresponding surface 36, 38 of the stencil 32 to permit the coating 20 to cover the entire circumference of the textile core 18.

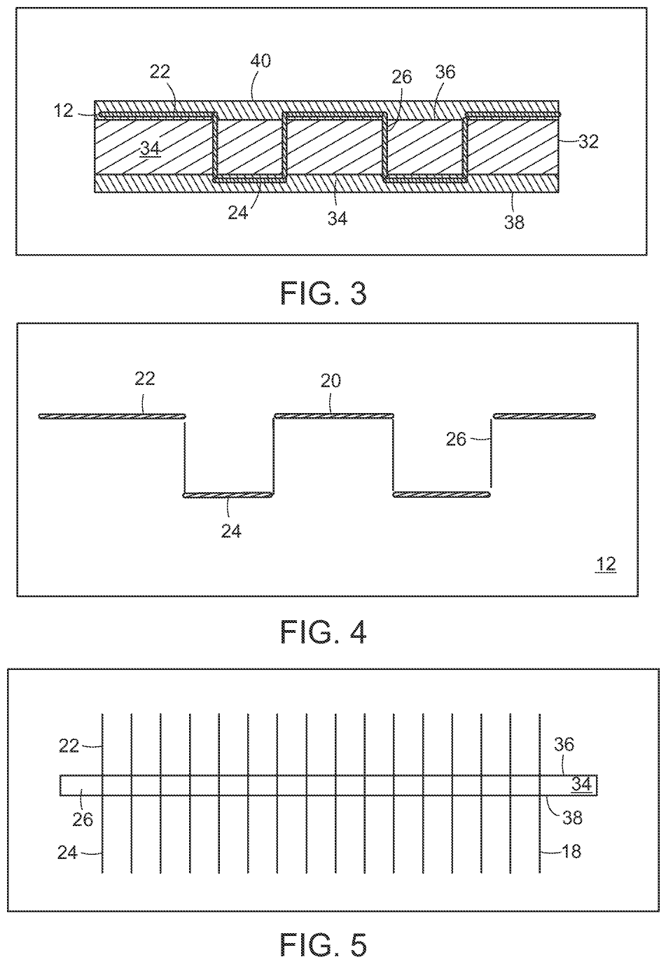

The process continues with depositing ink 40 on the stencil's top surface 36 and on its bottom surface 38, as shown in FIG. 3. This ink 40, upon being cured, becomes the conductive coating 20.

The ink 40 does not penetrate into the stencil's interior 34. As a result, those segments 26 of the textile core 18 within the stencil 32 remain uncoated. These become the gap segments 26, with the length of each gap segment 26 being the thickness of the stencil 32. However, the ink 40 does coat the surface of those segments of the textile core 18 that remain outside of the stencil 32. These segments become the source and drain segments 22, 24.

A useful ink 40 is carbon ink because of its low cost, its liquidity, the ease with which it can be rapidly applied during a high throughput fabrication process, and the fact that it tends to crystallize into graphite, which has reasonable electrical conductivity. The resulting graphite coating 20 is also compatible with gel electrolytes and thus permits the use of an ion gel 16 to control the thread-based transistor 10.

To prevent pooling of excess carbon ink 40 at the interface between the textile core 18 and the stencil 32 and to suppress seepage through that interface, it is useful to optimize the ink's viscosity.

A useful material for use as the rectangular stencil 32 is one that is flexible and somewhat elastic so that a tight seal can be formed at the point at which the textile core 18 penetrates the stencil 32. This suppresses any tendency for ink 40 to seep into that portion of the textile core 18 that is within the stencil's interior 34. A suitable material for such use is ECOFLEX™.

To minimize the possibility of leakage, it is useful to stretch the stencil 32 and to then pierce it at selected locations, thus forming holes having a stretched diameter. The textile core 18 is then passed through these holes while the stencil 32 remains stretched. The stencil 32 is then released so that it is free to contract. As a result, the holes thus created contract into a relaxed diameter. This forms a seal at the intersection of the textile core 18 with the top and bottom surfaces of the stencil 32. Preferably, the hole's relaxed diameter is less than that of the textile core 18. This promotes a tight seal that establishes a clear demarcation of the gap segment 26 in the finished channel thread 12.

Finally, the stencil 32 is removed, as shown in FIG. 4. This leaves behind a completed channel thread 12 having source segments 22, exposed segments 26, and drain segments 24. Particular practices include those in which the stencil 32 is removed by dissolution, melting, etching, or cutting. The resulting channel thread 12 can then be cut to form individual transistors 10.

The stencil 32 forms exposed segments 26 of equal length. The lengths of the source segments 22 and the drain segments 24 can, however, be made variable.

FIG. 5 illustrates another method that avoids having to cut the channel thread 12 to form individual transistors 10. In this embodiment, plural textile cores 18 are inserted through corresponding holes in the stencil 32.

In some practices, it is useful to have only a thin layer of polymer to reduce electrical shielding and electrochemical doping of the polymer by the ion gel that will eventually surround it. A useful polymer is a semiconducting polymer. In those cases in which the polymer is poly(3-hexylthiophene), it is useful to mix the poly(3-hexylthiophene) with a solution of 99% anhydrous 1,2-dichlorobenzene and to dropcast the resulting mixture into the gap segment 26 followed by removal of any excess mixture, either by placing the channel thread 12 into an oven, for example for twenty minutes at 50° C., or by capillary action using an absorbent material.

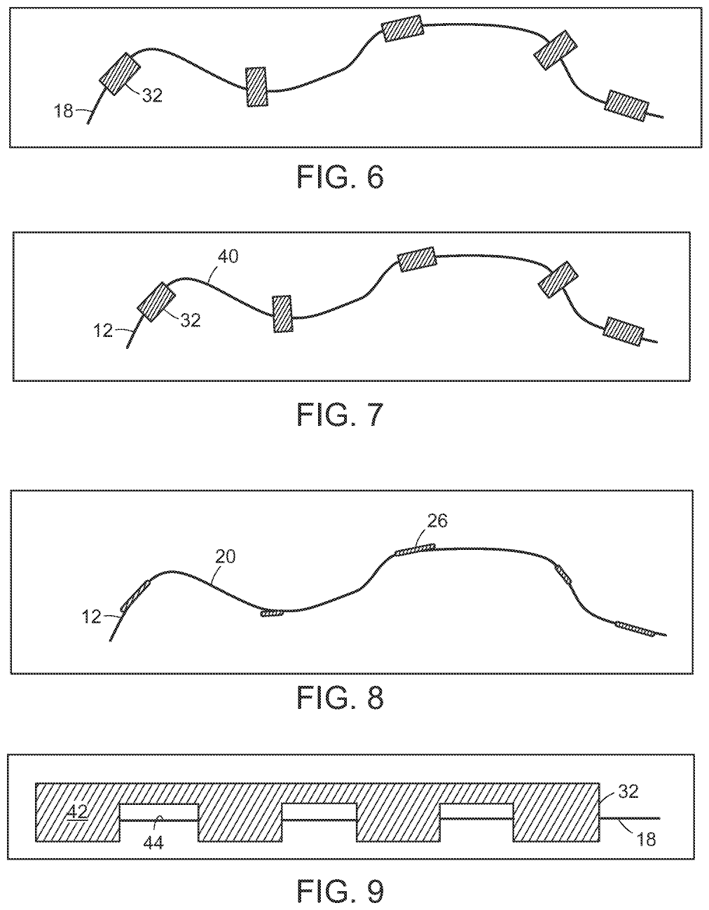

The manufacturing methods illustrated in FIGS. 2-5 result in gap segments 26 of equal length, namely the thickness of the stencil 32. In another practices which is shown in FIG. 6, the textile core 18 passes through a stencil set that comprises multiple stencils 32, each of which forms its own gap segment 26. As a result, it is possible to form gap segments 26 of different lengths by using stencils 32 of different thicknesses.

In the embodiment shown in FIG. 6, the stencils 32 are thus arranged in a manner similar to beads on a string. The textile core 18 is then coated with ink 40, as shown in FIG. 7. The portions of the textile core 18 inside the stencils 32 are kept free of ink 40, thus forming the gap segments 26 shown in FIG. 8 with the stencils 32 having been removed and the ink 40 having been cured to form the conductive coating 20.

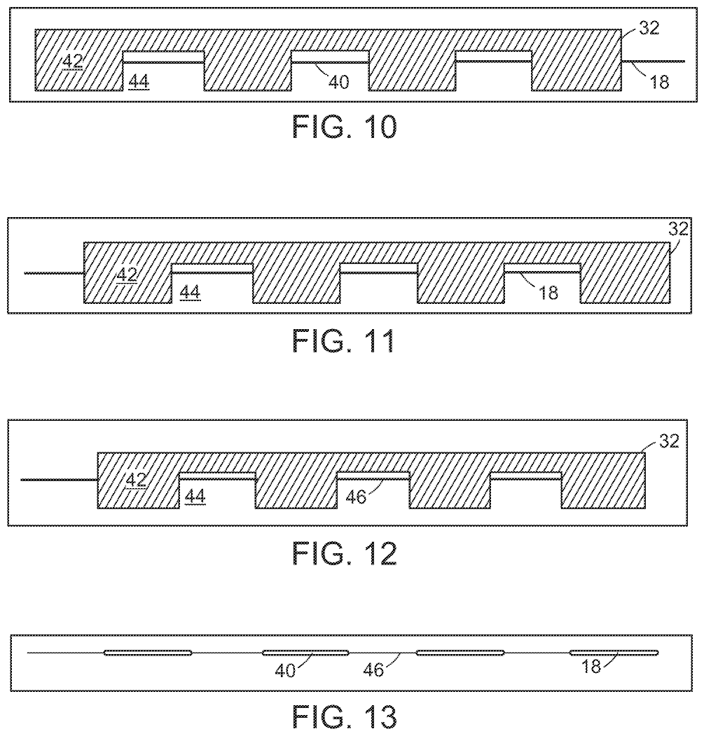

FIG. 9 shows textile core 18 passing through a corrugated stencil 32 having projections 42 that form recesses 44 therebetween. Those segments of the textile core 18 that are in the recesses 44 are then coated with what is, for purposes of FIG. 9, a first ink 40, as shown in FIG. 10.

After this first coating step, the textile core 18 is advanced through the corrugated stencil 32 so that those segments that were formerly within the recesses 44 are now inside the projections 42, as shown in FIG. 11. In the illustrated embodiment, the textile core 18 has been advanced in a leftward direction.

The uncoated segments of the textile core 18 that have been moved into the recesses 44 are then coated with a second ink 46, as shown in FIG. 12. However, those segments that have already been coated by the first ink 40 are protected from being coated again as a result of having been moved into the projections 42. Removing the stencil 32 thus leaves behind a textile core 18 that has been coated with first and second inks 40, 46, as shown in FIG. 13.

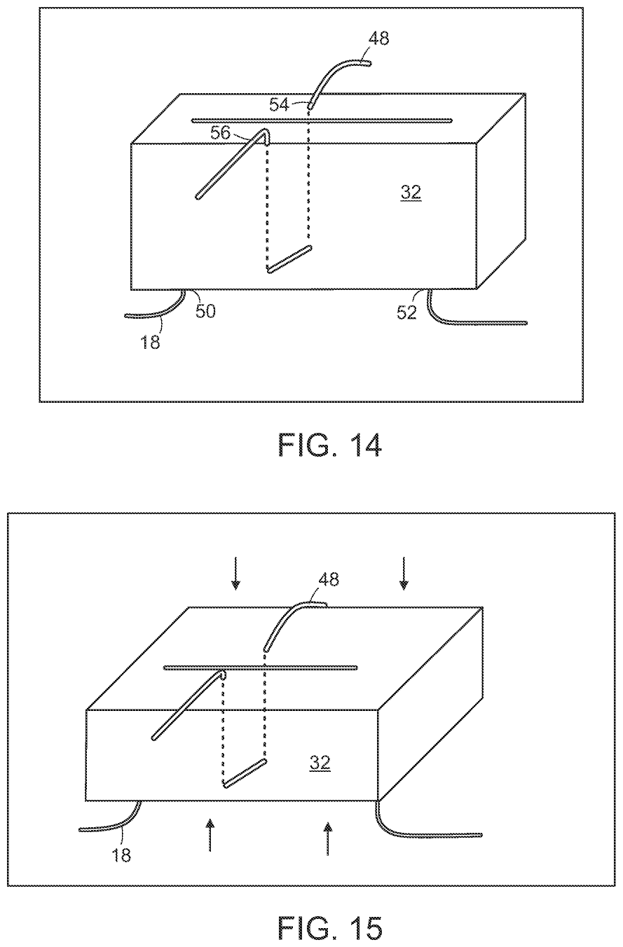

FIG. 14 shows an alternative embodiment of a stencil 32 that accommodates a first textile core 18 and a second textile core 48. The stencil 32 is a rectangular prism having first, second, third, and fourth holes 50, 52, 54, 56. The first textile core 18 passes through the first and second holes 50, 52 and extends along the stencil's length. The second textile core 48 passes through the third and fourth holes 54, 56 and extends along the stencil's width. This stencil 32 forms two exposed segments 26 having the same length, which is the stencil's height. Removal of the stencil 32 thus results in formation of two channel threads with exposed segments 26 of the same length.

In those cases in which the stencil 32 comprises an elastic material that compresses in response to applied pressure, it is possible to retain the stencil 32 and to use the resulting device as a pressure sensor. As shown in FIG. 15, application of a pressure would reduce the thickness of the stencil 32, thus increasing capacitance between the first and second channel textile cores 18, 48. This provides the basis for a voltage signal that varies in response to compression, and hence to applied pressure.

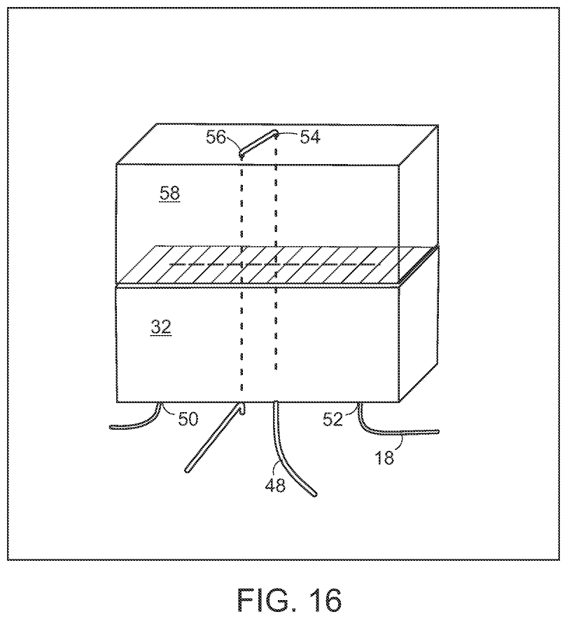

In the embodiment shown in FIG. 14, the first and second textile cores 18, 48 are kept apart as a result of being on opposite faces of the same stencil 32. However, it is also possible to stack a second stencil 58 on top of what would now be a first stencil 32, as shown in FIG. 16. The third and fourth holes 54, 56 would thus be aligned so that the second textile core 48 could pass through both the first and second stencils 32, 58. As a result, the first and second textile cores 18, 48 can be kept apart.

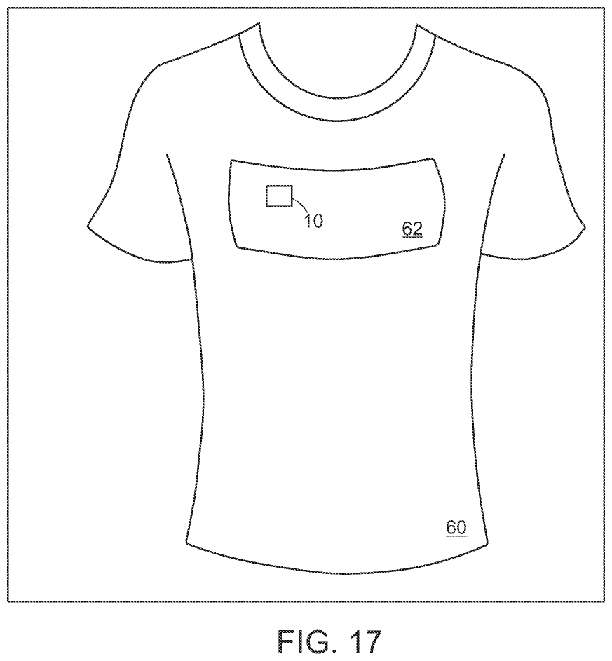

FIG. 17 shows a flexible substrate 60 comprising flexible electronics 62 attached thereto. The flexible electronics 62 comprises one or more transistors 10 along the lines of that shown in FIG. 1. In FIG. 17, the flexible substrate 60 is a shirt. However, other flexible substrates 60, such as flexible displays, can also be used.

Having described the invention and a preferred embodiment thereof, what is claimed as new and secured by Letters Patent is:

1. A manufacture comprising a thread-based transistor, said thread-based transistor comprising a channel thread, a gate wire, and an ion gel, wherein said channel thread comprises a textile core that comprises a source segment, a drain segment, and a gap segment that is between said source segment and said drain segment, wherein said source segment and said drain segment are coated by a conductive coating, wherein said gap segment is coated by a semiconducting material, and wherein said ion gel provides electrical coupling between said gap segment and said gate wire.

2. The manufacture of claim 1, wherein said textile core comprises linen.

3. The manufacture of claim 1, wherein said conductive coating comprises graphite.

4. The manufacture of claim 1, wherein said gate wire comprises a gold wire.

5. The manufacture of claim 1, wherein said thread-based transistor is an elastic transistor.

6. The manufacture of claim 1, wherein said semiconducting material comprises a semiconducting polymer.

7. The manufacture of claim 1, wherein said semiconducting material comprises poly(3-hexylthiophene).

8. The manufacture of claim 1, wherein said semiconducting material comprises carbon nanotubes.

9. The manufacture of claim 1, wherein said semiconducting material comprises graphene.

10. The manufacture of claim 1, wherein said semiconducting material comprises reduced graphene-oxide.

11. The manufacture of claim 1, wherein said semiconducting material comprises poly(3,4-ethylenedioxythiophene) polystyrene sulfonate.

12. The manufacture of claim 1, wherein said semiconducting material comprises molybdenum disulfide.

13. The manufacture of claim 1, wherein said semiconducting material comprises tungsten selenide.

14. The manufacture of claim 1, wherein said gap segment has an average length of under one millimeter.

15. The manufacture of claim 1, further comprising clothing that comprises wearable electronic circuitry incorporated therein, wherein said transistor is a constituent of said wearable electronic circuitry.

16. A method comprising manufacturing a thread-based transistor that comprises a channel thread having a source segment, a drain segment, and a gap segment between said source and drain segments, wherein manufacturing said thread-based transistor comprises forming said channel thread by passing a textile core through a stencil set that comprises a stencil such that a portion of said textile core that is to become said gap segment is inside said stencil and portions of said textile core that are to become said source and drain segments are outside any stencil, applying a conductive coating onto said portions of said textile core that are outside any stencil, thereby forming said source and drain segments, and removing said stencil set, thereby exposing said gap segment.

17. The method of claim 16, wherein said stencil comprises a first surface, a second surface, and a hole that extends between said first surface and said second surface, wherein passing said textile core through said stencil comprises passing said textile core through said hole.

18. The method of claim 16, wherein said textile core has a cross-sectional area, wherein said stencil comprises a first surface, a second surface, and a hole that extends between said first surface and said second surface, wherein said hole transitions between first and second cross-sectional areas, said second cross-sectional area of said hole being less than said cross-sectional area of said textile core, wherein passing said textile core through said stencil comprises causing said hole to have said first cross-sectional area, passing said textile core through said hole while said hole has said first cross-sectional area, with said textile core having passed through said hole, causing said hole to transition into said second cross-sectional area.

19. The method of claim 16, wherein said textile core has a cross-sectional area, wherein said stencil is an elastic stencil that comprises a first surface, a second surface, and a hole that extends between said first surface and said second surface, wherein passing said textile core through said stencil comprises stretching said stencil, while said stencil is stretched, passing said textile core through said hole, and releasing said stencil, thereby entrapping said textile core in said hole.

20. The method of claim 16, wherein said gap segment is a first gap segment and wherein forming said channel thread further comprises passing said textile core through said stencil a second time to permit formation a second gap segment on said channel thread.

21. The method of claim 16, wherein said gap segment is one of a plurality of gap segments and wherein forming said channel thread further comprises causing said textile core to pass through said stencil multiple times, wherein each pass through said stencil defines a gap segment from said plurality of gap segments, said gap segments being parallel to each other in said stencil.

22. The method of claim 16, wherein said gap segment is one of a plurality of gap segments and wherein forming said channel thread further comprises causing said textile core to pass through said stencil multiple times, wherein each pass through said stencil defines a gap segment from said plurality of gap segments, said gap segments being colinear with each other in said stencil.

23. The method of claim 16, wherein said gap segment is one of a plurality of gap segments and wherein forming said channel thread further comprises causing said textile core to pass through projections in said stencil and through recesses that separate said projections from each other, wherein each portion of said channel thread that is inside a projection defines one of said gap segments.

24. The method of claim 16, wherein said stencil is a first stencil and said stencil set comprises a second stencil and wherein passing said textile core through said stencil set comprises passing said textile core through a second stencil so as to form an additional gap segment.

25. The method of claim 16, wherein said stencil is a first stencil and said stencil set comprises a second stencil, wherein said gap segment is a first gap segment, and wherein passing said textile core through said stencil set comprises passing said textile core through a second stencil so as to form a second gap segment that has a length that differs from that of said first gap segment.

26. The method of claim 16, wherein said gap segment is a first gap segment and wherein forming said channel thread further comprises passing said textile core through said stencil a second time to permit formation a second gap segment on said channel thread, said second gap segment having a length that is equal to that of said first gap segment.

27. The method of claim 16, further comprising providing a gate wire, coating said gap segment with a semiconducting material, and providing an ion gel between said gate wire and said coated gap segment.

28. The method of claim 16, wherein applying said conductive coating comprises applying liquid carbon ink onto said textile core and onto said stencil.

29. The method of claim 16, further comprising incorporating said transistor into flexible circuitry that is on a flexible substrate.
